(19) United States
(12) Patent Application Publication
(10) Pub. No.: US 2026/0295626 A1
(43) Pub. Date: Oct. 1, 2026

(54) AUTOMATED INDUSTRIAL COATING SYSTEM

(71) Applicant: THE HONG KONG UNIVERSITY OF SCIENCE AND TECHNOLOGY (GUANGZHOU), Guangzhou (CN)

(72) Inventors: Hang ZHAO, Guangzhou (CN); Tongyi ZHANG, Guangzhou (CN); Pengxiao BAO, Guangzhou (CN); Lujiang LIU, Guangzhou (CN); Zhanpeng LI, Guangzhou (CN); Kai CHEN, Guangzhou (CN); Huachen CUI, Guangzhou (CN)

(21) Appl. No.: 19/310,426

(22) Filed: Aug. 26, 2025

(30) Foreign Application Priority Data
Mar. 25, 2025 (CN) 202510356342.5

(51) Int. Cl. B05C 1/02; B05C 11/04; B05C 11/06; B05C 13/02; B05D 3/02

(52) U.S. Cl. CPC B05C 1/025; B05C 11/045; B05C 11/06; B05C 13/02; B05D 3/0254

(57) ABSTRACT

An automated industrial coating system is disclosed, including a frame fixedly mounted on a base, a blade-coating system installed on the frame; a displacement module, a movable end of the displacement module being configured to be movable to a position directly below the blade-coating system, a support configured to be vertically movable on the movable end of the displacement module, an annealing system configured to be vertically movable on the support, an in-situ detection module fixedly mounted on a bottom of the support, and a substrate fixation module fixedly mounted on a top of the support.

### TECHNICAL FIELD

The present disclosure relates to the technical field of high-precision thin-film coating devices, and particularly to an automated industrial coating system.

### BACKGROUND

In the field of modern industrial automation, coating processes are widely applied to surface treatments of various industrial products, including for example coating on the surface of a substrate made of metal, plastic, glass, or the like. Coating systems not only need to achieve efficient and uniform coating operations but also require high-precision quality detection and timely annealing treatments to ensure the adhesion of the coating layer and product quality. Traditional coating systems usually include coating devices, quality detection devices, and annealing devices, which are often independent from each other, resulting in large space occupation and low production efficiency. This makes it difficult to achieve continuous and automated coating, detection, and annealing processes.

In the traditional coating systems, the coating device, quality detection device, and annealing device are typically separately set up, leading to bulky equipment, large floor space. This is not conducive to production line layouts and optimizations. Moreover, since coating, detection, and annealing require transferring between different devices, this not only fails to realize in-situ detection during the coating process but also increases production time, causing contamination and damage to the coating layer, thus affecting the final product quality. Automated devices for high-precision coating systems are even rarer as high-precision film thickness, generally ranging from 10 to 800 nm, is mainly achieved through manual coating. Therefore, there is an urgent need for an automated industrial coating system to address these issues.

### SUMMARY

An objective of the present disclosure is to provide an automated industrial coating system to solve the above issues.

In order to achieve the above objective, the present disclosure provides the following technical schemes:

An automated industrial coating system is provided, including:
a frame fixedly mounted on a base;
a blade-coating system installed on the frame;
a displacement module, a movable end of the displacement module being configured to be movable to a position directly below the blade-coating system;
a support configured to be vertically movable on the movable end of the displacement module;
an annealing system configured to be vertically movable on the support;
an in-situ detection module fixedly mounted on a bottom of the support; and
a substrate fixation module fixedly mounted on a top of the support.

Optionally, the displacement module includes a linear motor, a fixed end of the linear motor is fixedly mounted on the base, a movable end of the linear motor is fixedly mounted with a fixed end of a lift unit, and a movable end of the lift unit is connected to the support.

Optionally, the lift unit includes a second lift motor, a fixed end of the second lift motor is fixedly mounted on the movable end of the linear motor, a movable end of the second lift motor is fixedly mounted with a lift stage, and the support is fixedly mounted on the lift stage.

Optionally, the in-situ detection module is fixedly mounted on the lift stage and located between the support and the lift stage.

Optionally, the annealing system includes a thermal stage, a bottom of the thermal stage is fixedly mounted with a movable end of a first lift motor, and a fixed end of the first lift motor is mounted on the top of the support.

Optionally, the substrate fixation module includes two symmetrically arranged vacuum chucks, the two vacuum chucks are fixedly mounted on the support and respectively located on two sides of the thermal stage.

Optionally, the blade-coating system includes a coating blade and an air knife, both the coating blade and the air knife are fixedly mounted on the frame, and the coating blade is located in front of the air knife in a blade-coating direction.

Compared with the prior art, the present disclosure has the following advantages and technical effects:

During use, the substrate is placed on the support and fixed by the substrate fixation module, maintaining stability of the substrate during the coating process. The support is moved to the position below the blade-coating system by the displacement module. During the movement, the blade-coating system uniformly applies the coating on the substrate, and the in-situ detection module is used to detect the coating quality. This device integrates the annealing system, in-situ detection module, and substrate fixation module onto the support, achieving high integration, and significantly reducing the equipment size. Moreover, since the annealing system and in-situ detection module are integrated on the support, in-situ detection and annealing can be performed during the blade-coating process, improving production efficiency and aiding in production quality control.

### BRIEF DESCRIPTION OF DRAWINGS

In order to illustrate more clearly technical schemes in embodiments of the present disclosure or the related art, the accompanying drawings used in description of the embodiments will be briefly described below. Obviously, the accompanying drawings in the following description are only some embodiments of the present disclosure, and for those of ordinary skill in the art, other drawings can be derived on the basis of these drawings without any inventive effort.

FIG. 1 is a schematic diagram of the present disclosure;

FIG. 2 is a schematic diagram of an annealing system of the present disclosure; and

FIG. 3 is a schematic diagram of the annealing system of the present disclosure from another view.

In the drawings: 1. base; 2. linear motor; 3. in-situ detection module; 4. coating blade; 5. air knife; 6. frame; 7. support; 8. lift stage; 9. vacuum chuck; 10. thermal stage; 11. first lift motor; and 12. second lift motor.

### DETAILED DESCRIPTION

The technical schemes in the embodiments of the present disclosure are clearly and completely described in the following with reference to the drawings in the embodiments of the present disclosure. It is obvious that the described embodiments are only some of the embodiments of the present disclosure and are not all the embodiments thereof. All other embodiments obtained by those of ordinary skill in the art based on the embodiments of the present disclosure without inventive effort fall within the scope of the present disclosure.

In order to make the above-mentioned objective, features and advantages of the present disclosure more obvious and easier to understand, the present disclosure will be described in detail below with reference to the accompanying drawings and specific embodiments.

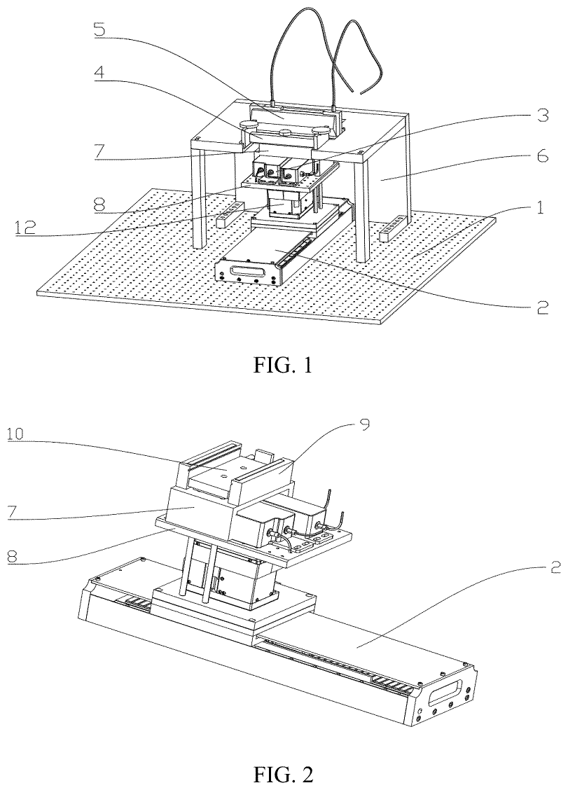

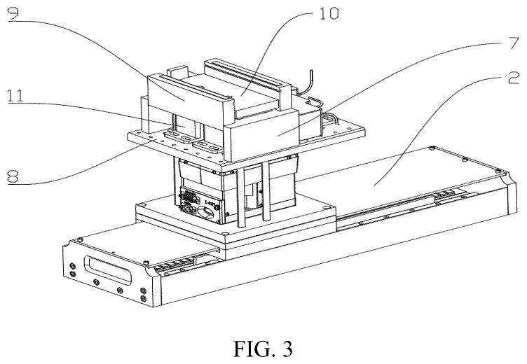

Referring to FIGS. 1 to 3, the present disclosure discloses an automated industrial coating system, including:
a frame 6, the frame 6 being fixedly mounted on a base 1;
a blade-coating system installed on the frame 6;
a displacement module, a movable end of the displacement module being configured to be movable to a position directly below the blade-coating system;
a support 7 configured to be vertically movable on the movable end of the displacement module;
an annealing system configured to be vertically movable on the support 7;
an in-situ detection module 3 fixedly mounted on a bottom of the support 7; and
a substrate fixation module fixedly mounted on a top of the support 7.

During use, the substrate is placed on the support 7 and fixed by the substrate fixation module, maintaining stability of the substrate during the coating process. The support 7 is moved to the position below the blade-coating system by the displacement module. During the movement, the blade-coating system uniformly applies the coating on the substrate, and the in-situ detection module 3 is used to detect the coating quality. This device integrates the annealing system, the in-situ detection module 3, and the substrate fixation module onto the support 7, achieving high integration, and significantly reducing the equipment size. Moreover, since the annealing system and the in-situ detection module 3 are both integrated on the support 7, in-situ detection and annealing can be performed during the blade-coating process, improving production efficiency and facilitating production quality control.

Combining in-situ detection technologies (such as photoluminescence (PL) and absorption spectroscopy) with automated manufacturing equipment helps improve the intelligence and automation level of the preparation process, especially in the preparation process of perovskite materials. These in-situ detection technologies can not only monitor the optoelectronic properties of materials in real time but also provide instant feedback on the material state, thereby optimizing the preparation process and improving material quality and device performance.

The in-situ detection module 3 includes PL and ultraviolet-visible spectroscopy (UV-vis) detection systems: this device integrates PL and UV-vis optical detection modules to monitor the optical characteristics of the coating in real time. These detection systems are capable of conducting high-precision evaluations of the thickness, uniformity, optical absorption, and luminescent characteristics of coatings, assisting in the optimization of coating quality. Both PL and UV-vis optical detection modules are existing technologies, so no further explanation will be provided.

The integration of PL and absorption spectroscopy instruments with preparation equipment allows real-time monitoring of the photoelectric properties of materials. During the material preparation process, data can be collected in real time to guide the adjustment of process parameters.

As an optional embodiment, the displacement module includes a linear motor 2, a fixed end of the linear motor 2 is fixedly mounted on the base 1, a movable end of the linear motor 2 is fixedly mounted with a fixed end of a lift unit, and a movable end of the lift unit is connected to the support 7.

As an optional embodiment, the lift unit includes a second lift motor 12, a fixed end of the second lift motor 12 is fixedly mounted on a movable end of the linear motor 2, a movable end of the second lift motor 12 is fixedly mounted with a lift stage 8, and the support 7 is fixedly mounted on the lift stage 8.

As an optional embodiment, the in-situ detection module 3 is fixedly mounted on the lift stage 8 and located between the support 7 and the lift stage 8.

As an optional embodiment, the annealing system includes a thermal stage 10, a bottom of the thermal stage 10 is fixedly mounted with a movable end of a first lift motor 11, and a fixed end of the first lift motor 11 is fixedly mounted on the top of the support 7.

The thermal stage 10 is used to heat the coating material, promoting the curing and annealing processes of the coating. The thermal stage 10 can adjust the temperature and heating time to accommodate the annealing requirements of different materials, thereby improving the quality and stability of the coating. The temperature range of the thermal stage 10 is from room temperature (RT) to 200 degrees Celsius.

The arrangement of the first lift motor 11 allows for precise adjustment of the height of the first lift motor 11, ensuring that the substrate can directly contact the thermal stage 10 during the annealing process, and during the blade-coating process, the substrate remains at room temperature through a thermal insulation plate and an air gap.

A sliding groove for sliding of the thermal insulation plate is provided in the support 7.

As an optional embodiment, the substrate fixation module includes two symmetrically arranged vacuum chucks 9, the two vacuum chucks 9 are fixedly mounted on the support 7 and respectively located on two sides of the thermal stage 10.

The vacuum chucks 9 ensure that the substrate remains stable without displacement or deformation throughout the blade-coating and annealing processes. This design improves the stability and precision of the equipment operation.

As an optional embodiment, the blade-coating system includes a coating blade 4 and an air knife 5, both the coating blade 4 and the air knife 5 are fixedly mounted on the frame 6, and the coating blade 4 is located in front of the air knife 5 in the blade-coating direction.

The air knife 5 and the coating blade 4 are fixed on the frame 6, with the air knife 5 configured to adjust the humidity of the coating surface and remove excess coating material from the surface, ensuring the uniformity of the coating. The coating blade 4 is configured to uniformly apply the coating material on the substrate surface, precisely controlling the coating thickness.

Through the adjustable lift stage 8, the support 7 carrying the attached substrate is raised and lowered to ensure that the coating blade can maintain an appropriate gap with the substrate surface, thereby ensuring the consistency of the coating. The lift function of the lift stage 8 allows the equipment to flexibly adapt to substrates of different sizes and adjust the coating position.

This device uses an automated control system, where the equipment adjusts various subsystems (such as blade-coating, annealing, detection, etc.) to work collaboratively through the automated control system, achieving efficient and precise coating preparation and quality control. The control system can also automatically adjust the blade-coating and annealing parameters based on real-time detection data, optimizing the workflow. The full-process automation can also be achieved in conjunction with a robotic arm system.

The robotic arm and automated process are as follows:

### 1. Substrate Placement and Vacuum Chuck Operation

The robotic arm takes a substrate and places the substrate on the vacuum chucks 9: The robotic arm takes the substrate from a designated position and accurately places the substrate on the vacuum chucks 9 of the equipment. The activation of the vacuum chucks 9 is triggered by an automated control system of the robotic arm, ensuring that the substrate is securely fixed on the work platform, avoiding sliding or displacement of the substrate.

### 2. Liquid Dispensing Operation

The robotic arm uses a liquid dispenser for liquid dispensing: Once the substrate is secured, the robotic arm takes out the liquid dispenser and accurately dispenses a formulation liquid onto the substrate, ensuring the uniformity and thickness of the coating. The positioning of the liquid dispenser and the amount of liquid dispensed are precisely adjusted by a control system to meet different coating requirements.

### 3. Blade-Coating Operation

The second lift motor 12 and slit adjustment: The second lift motor 12 adjusts the slit height according to the formulation requirements to ensure the precision of the blade-coating operation. The height adjustment of the slit can be dynamically adjusted according to the viscosity of the liquid and the requirements of the substrate surface.

The linear motor 2 performs precise horizontal movement during the blade-coating process, while the second lift motor 12 executes precise vertical movement during the blade-coating process, synchronously completing the uniform application of the coating with the coating blade 4.

The air knife 5 starts synchronously: During the blade-coating process, the air knife 5 starts synchronously to blow away excess coating material and control the uniformity of the coating. At the same time, the airflow from the air knife 5 helps promote the initial crystallization of the coating.

### 4. Annealing Preparation

The robotic arm takes the thermal insulation plate: After the blade-coating is completed, the robotic arm takes out the thermal insulation plate and places it on the substrate to ensure uniform heat distribution of the substrate during the annealing process.

The lifting of the thermal stage 10 and annealing: The position of the first lift motor 11 is adjusted, lifting the thermal stage 10 from below into contact with the substrate, ensuring that heat is evenly transferred from below to the substrate. The substrate begins the annealing process, promoting the crystallization, curing, and performance enhancement of the coating.

Compared with the existing technology, the present disclosure can achieve fully automated operations: The multiple functional modules integrated with the robotic arm (such as substrate placement, liquid dispensing, blade-coating, annealing, etc.) achieve fully automated operations, greatly improving production efficiency and ensuring the consistency of coating quality.

Multi-functional collaborative work: Multiple components such as the air knife, the lift stage, the displacement stage, and the thermal stage work collaboratively, ensuring that every link from coating to annealing can be precisely controlled to meet high-precision industrial requirements.

Dynamic adjustment: The equipment can automatically adjust various parameters (such as liquid dispensing amount, blade-coating slit height, air knife airflow strength, etc.) based on actual operating conditions to adapt to different substrates and coating requirements.

In the description of the present disclosure, it should be understood that, descriptions relating to orientation, for example, orientation or positional relationships indicated by “longitudinal”, “lateral”, “up”, “down”, “front”, “back”, “left”, “right”, “vertical”, “horizontal”, “top”, “bottom”, “inside”, “outside”, etc. are based on the orientation or positional relationships shown in the accompanying drawings, and are to facilitate the description of the present disclosure only, rather than indicating or implying that the device or element referred to must have a specific orientation or be constructed and operated in a specific orientation, and therefore cannot be construed as limiting the present disclosure.

The aforementioned embodiments are merely descriptions of the preferred implementations of the present disclosure, and are not intended to limit the scope of the present disclosure. Within the principle of the present disclosure, any modifications, improvements, or variations to the technical schemes of the present disclosure made by those skilled in the art should be included within the scope of protection defined by the claims of the present disclosure.

What is claimed is:

1. An automated industrial coating system, comprising:
a frame, the frame being fixedly mounted on a base;
a blade-coating system installed on the frame;
a displacement module, a movable end of the displacement module being configured to be movable to a position directly below the blade-coating system;
a support configured to be vertically movable on the movable end of the displacement module;
an annealing system configured to be vertically movable on the support;
an in-situ detection module fixedly mounted on a bottom of the support; and
a substrate fixation module fixedly mounted on a top of the support.

2. The automated industrial coating system of claim 1, wherein the displacement module comprises a linear motor, a fixed end of the linear motor is fixedly mounted on the base, a movable end of the linear motor is fixedly mounted with a fixed end of a lift unit, and a movable end of the lift unit is connected to the support.

3. The automated industrial coating system of claim 2, wherein the lift unit comprises a second lift motor, a fixed end of the second lift motor is fixedly mounted on the movable end of the linear motor, a movable end of the second lift motor is fixedly mounted with a lift stage, and the support is fixedly mounted on the lift stage.

4. The automated industrial coating system of claim 3, wherein the in-situ detection module is fixedly mounted on the lift stage and located between the support and the lift stage.

5. The automated industrial coating system of claim 1, wherein the annealing system comprises a thermal stage, a bottom of the thermal stage is fixedly mounted with a movable end of a first lift motor, and a fixed end of the first lift motor is mounted on the top of the support.

6. The automated industrial coating system of claim 5, wherein the substrate fixation module comprises two symmetrically arranged vacuum chucks, the two vacuum chucks are fixedly mounted on the support and respectively located on two sides of the thermal stage.

7. The automated industrial coating system of claim 1, wherein the blade-coating system comprises a coating blade and an air knife, both the coating blade and the air knife are fixedly mounted on the frame, and the coating blade is located in front of the air knife in a blade-coating direction.
